(19) United States
(12) Patent Application Publication
(10) Pub. No.: US 2007/0247946 A1
(43) Pub. Date: Oct. 25, 2007

(54) Bulk erase tool

(76) Inventor: Taeyong Yoon, San Jose, CA (US)

Correspondence Address: WAGNER, MURABITO & HAO LLP;Two North Market Street, Third Floor, San Jose, CA, 95113, US

(21) Appl. No.: 11/408,722

(22) Filed: Apr. 21, 2006

(51) Int. Cl. G11C 7/00

(52) U.S. Cl. 365/218

(57) ABSTRACT

A bulk erase tool is provided. The bulk erase tool includes first polarity top and bottom main erase magnets. Additionally, the bulk erase tool includes second polarity top and bottom main erase magnets. The bulk erase tool also includes first polarity top and bottom cancel magnets at portions of the second polarity top and bottom main magnets. The bulk erase tool additionally includes second polarity top and bottom cancel magnets at portions of the first polarity top and bottom main magnets. In so doing, the first polarity top and bottom cancel magnets and the second polarity top and bottom cancel magnets reduce the bulk erase tool field strength at a first portion of the bulk erase tool.

### TECHNICAL FIELD

This invention relates to the field of hard disk drives, and more particularly to a bulk erase tool.

### BACKGROUND ART

Hard disk drives are used in almost all computer system operations. In fact, most computing systems are not operational without some type of hard disk drive to store the most basic computing information such as the boot operation, the operating system, the applications, and the like. In general, the hard disk drive is a device which may or may not be removable, but without which the computing system will generally not operate.

The basic hard disk drive model was established approximately 50 years ago and resembles a phonograph. That is, the hard drive model includes a storage disk or hard disk that spins at a standard rotational speed. An actuator arm with a suspended slider is utilized to reach out over the disk. The arm carries a head assembly that has a magnetic read/write transducer or head for reading/writing information to or from a location on the disk. The complete head assembly, e.g., the suspension and head, is called a head gimbal assembly (HGA).

In operation, the hard disk is rotated at a set speed via a spindle motor assembly having a central drive hub. Additionally, there are circumferential tracks evenly spaced at known intervals across the disk. When a request for a read of a specific portion or track is received, the hard disk aligns the head, via the arm, over the specific track location and the head reads the information from the disk. In the same manner, when a request for a write of a specific portion or track is received, the hard disk aligns the head, via the arm, over the specific track location and the head writes the information to the disk.

Over the years, the disk and the head have undergone great reductions in their size. Much of the refinement has been driven by consumer demand for smaller and more portable hard drives such as those used in personal digital assistants (PDAs), MP3 players, and the like. For example, the original hard disk drive had a disk diameter of 24 inches. Modern hard disk drives are much smaller and include disk diameters 3.5 to 1 inches (and even smaller 0.8 inch). Advances in magnetic recording are also primary reasons for the reduction in size.

Advances in magnetic recording are also primary reasons for the reduction in size. For example, advances have led to storage capacities in the range of 120 gigabytes (GB) per square inch of disk real estate. Thus, multi-hard disk drives have capacities in the range hundreds of gigabytes. In the present environment, even small improvements in storage techniques can produce large absolute changes in total capacity. For example, a 4% improvement in the capacity of a 250 GB hard disk drive results in an extra 10 GB of additional storage capacity. This is more than the original capacity of hard disk drives offered in the late 1990's.

After assembling the mechanical components to form the hard disk drive, servo patterns are written on the new disks to prepare the hard disk drives for customer use. However, there are cases when the servo patterns have to be re-written. In those cases, existing servo patterns have to be erased before new servo patterns may be re-written. For example, servo patterns have to be rewritten when the initial servo writing fails, if the servo writing was successful, but the disk drive fails functional tests, or if complete or partial disassembly and reassembly of the mechanical components is needed.

Generally, a bulk erase tool is a magnetic device used to erase the (servo or other) patterns on the disk of a hard disk drive. The advantage of using the bulk erase tool over using the head erase within the hard disk drive is the fast and easy operation of the bulk erase tool. For example, a head erase of the disk may take 20 minutes while a bulk erase of the disk may only take 10 seconds.

However, as disk coercivity becomes higher, the required magnetic field in the bulk erase tool also becomes higher and increases the possibility of damaging the motor magnet and heads of the hard disk drive. For example, one problem with the conventional bulk erase tool design is that the difference between the field at motor magnet and the field at the ID track is too small, i.e., the slope of the erase field curve is not sharp enough. If the drive is inserted deep inside the bulk eraser to erase the ID track then the motor magnet is also exposed to a strong magnetic field which leads to demagnetization of the motor magnet. However, if the drive insertion is adjusted such that no demagnetization of the motor magnet occurs, then the erase field acting on the ID track of the disk is not strong enough to completely erase the disk resulting in residual disk signals. These un-erased tracks have to head-erased which is time-consuming process.

### SUMMARY

A bulk erase tool is provided. The bulk erase tool includes first polarity top and bottom main erase magnets. Additionally, the bulk erase tool includes second polarity top and bottom main erase magnets. The bulk erase tool also includes first polarity top and bottom cancel magnets at portions of the second polarity top and bottom main magnets. The bulk erase tool additionally includes second polarity top and bottom cancel magnets at portions of the first polarity top and bottom main magnets. In so doing, the first polarity top and bottom cancel magnets and the second polarity top and bottom cancel magnets reduce the bulk erase tool field strength at a first portion of the bulk erase tool.

### BRIEF DESCRIPTION OF THE DRAWINGS

FIG. 1 is a plan view of an HDD with cover and top magnet removed in accordance with one embodiment of the present invention.

FIG. 2 is an exemplary diagram of a disk having circumferential tracks of pre-written timing information in accordance with an embodiment of the present invention.

FIG. 3a is a block diagram of one half of an exemplary bulk erase tool in accordance with one embodiment of the present invention.

FIG. 3b is a side sectional view of a complete exemplary bulk erase tool having both top and bottom magnet sets and the optional tray in accordance with one embodiment of the present invention.

FIG. 4 is a graph of the field magnitude of the bulk erase tool at 11.5 mm from the center of the spindle motor, the approximate hard disk drive motor magnet location, in accordance with one embodiment of the present invention.

FIG. 5 is a graph of the field magnitude of the bulk erase tool at 17.5 mm from the center of the spindle motor, the approximate hard disk drive ID track location, in accordance with one embodiment of the present invention.

FIG. 6 is a flowchart of a method for providing a bulk erase tool having a portion of reduced field strength in accordance with one embodiment of the present invention.

### BEST MODES FOR CARRYING OUT THE INVENTION

Reference will now be made in detail to the alternative embodiment(s) of the present invention, a bulk erase tool. While the invention will be described in conjunction with the alternative embodiment(s), it will be understood that they are not intended to limit the invention to these embodiments. On the contrary, the invention is intended to cover alternatives, modifications and equivalents, which may be included within the spirit and scope of the invention as defined by the appended claims.

Furthermore, in the following detailed description of the present invention, numerous specific details are set forth in order to provide a thorough understanding of the present invention. However, it will be recognized by one of ordinary skill in the art that the present invention may be practiced without these specific details. In other instances, well known methods, procedures, components, and circuits have not been described in detail as not to unnecessarily obscure aspects of the present invention.

Embodiments described herein provide a bulk erase tool design for both perpendicular (PR) and longitudinal (LR) recording media using an in-plane magnetic erase field. Moreover, unlike prior bulk erase tools, the present bulk erase tool will not demagnetize the motor magnet. Additionally, because the design provides sharp transition of the erase field with the cancel magnets collocated with the main erase magnets, the field strength near the motor magnet is lowered. At the same time, the field strength is increased near the data track. In other words, embodiments described herein provide a sharp transition of the erase field in the bulk erase tool.

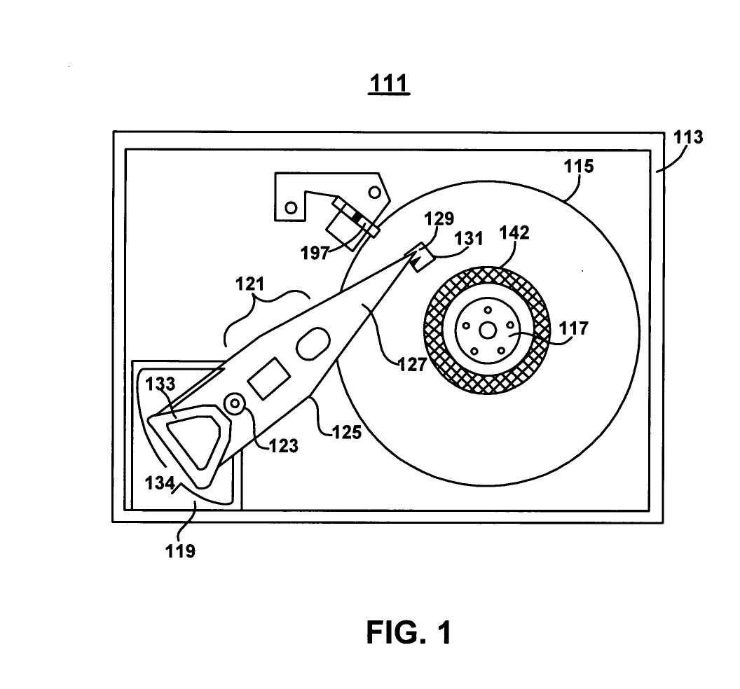

With reference now to FIG. 1, a schematic drawing of one embodiment of an information storage system comprising a magnetic hard disk file or drive 111 for a computer system is shown. Although a hard disk drive having a single disk is shown, embodiments of the invention are well suited for utilization on a hard disk drive having a plurality of disks therein. Furthermore, the single disk hard drive of FIG. 1 is merely one version of a plurality of hard disk drive configurations that may be utilized in conjunction with the present invention. For example, in one embodiment the hard disk drive 111 would use load/unload (L/UL) techniques with a ramp 197 and a nose limiter. In another embodiment, the drive 111 is a non L/UL drive, for example, a contact start-stop (CSS) drive having a textured landing zone 142 away from the data region of disk 115.

In the exemplary FIG. 1, Drive 111 has an outer housing or base 113 containing a disk pack having at least one media or magnetic disk 115. A spindle motor assembly having a central drive hub 117 rotates the disk or disks 115. An actuator comb 121 comprises a plurality of parallel actuator arms 125 (one shown) in the form of a comb that is movably or pivotally mounted to base 113 about a pivot assembly 123. A controller 119 is also mounted to base 113 for selectively moving the comb of arms 125 relative to disk 115.

In the embodiment shown, arm 125 has extending from it at least one cantilevered electrical lead suspension (ELS) 127. It should be understood that ELS 127 may be, in one embodiment, an integrated lead suspension (ILS) that is formed by a subtractive process. In another embodiment, ELS 127 may be formed by an additive process, such as a circuit integrated suspension (CIS). In yet another embodiment, ELS 127 may be a flex-on suspension (FOS) attached to base metal or it may be a flex gimbal suspension assembly (FGSA) that is attached to a base metal layer. The ELS may be any form of lead suspension that can be used in a data access storage device, such as a HDD. A magnetic read/write transducer 131 or head is mounted on a slider 129 and secured to a flexible structure called “flexure” that is part of ELS 127. The read/write heads magnetically read data from and/or magnetically write data to disk 115. The level of integration called the head gimbal assembly (HGA) is the head and the slider 129, which are mounted on suspension 127. The slider 129 is usually bonded to the end of ELS 127.

ELS 127 has a spring-like quality, which biases or presses the air-bearing surface of the slider 129 against the disk 115 to cause the slider 129 to fly at a precise distance from the disk as the disk rotates and air bearing develops pressure. The ELS 127 has a hinge area that provides for the spring-like quality, and a flexing interconnect that supports read and write traces through the hinge area. A voice coil 133, free to move within a conventional voice coil motor magnet assembly 134 (top pole not shown), is also mounted to arms 125 opposite the head gimbal assemblies. Movement of the actuator comb 121 by controller 119 causes the head gimbal assemblies to move along radial arcs across tracks on the disk 115 until the heads settle on their set target tracks. The head gimbal assemblies operate in a conventional manner and always move in unison with one another, unless drive 111 uses multiple independent actuators (not shown) wherein the arms can move independently of one another.

In general, the load/unload drive refers to the operation of the ELS 127 with respect to the operation of the disk drive. That is, when the disk 115 is not rotating, the ELS 127 is unloaded from the disk. For example, when the disk drive is not in operation, the ELS 127 is not located above the disk 115 but is instead located in a holding location on L/UL ramp 197 away from the disk 115 (e.g., unloaded). Then, when the disk drive is operational, the disk(s) are spun up to speed, and the ELS 127 is moved into an operational location above the disk(s) 115 (e.g., loaded). In so doing, the deleterious encounters between the slider and the disk 115 during non-operation of the HDD 111 are greatly reduced. Moreover, due to the movement of the ELS 127 to a secure off-disk location during non-operation, the mechanical ship shock robustness of the HDD is greatly increased.

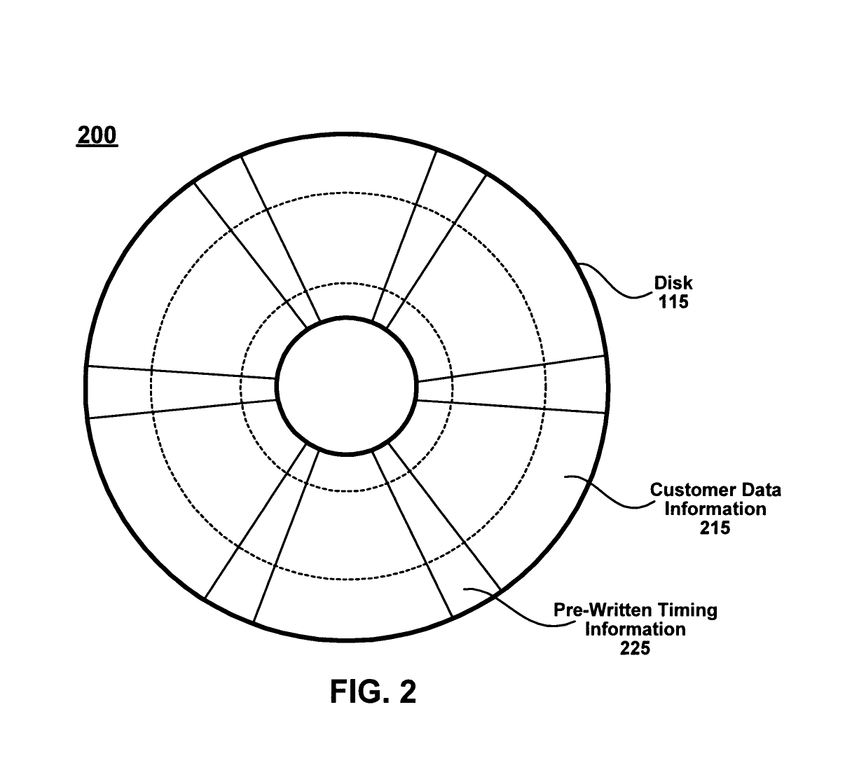

With reference now to FIG. 2, an exemplary diagram 200 of a disk 115 having circumferential tracks of pre-written timing information 225 and optional customer data information 215 is shown in accordance with one embodiment of the present invention. FIG. 2 is shown to illustrate one embodiment of data to be erased by the bulk erase tool.

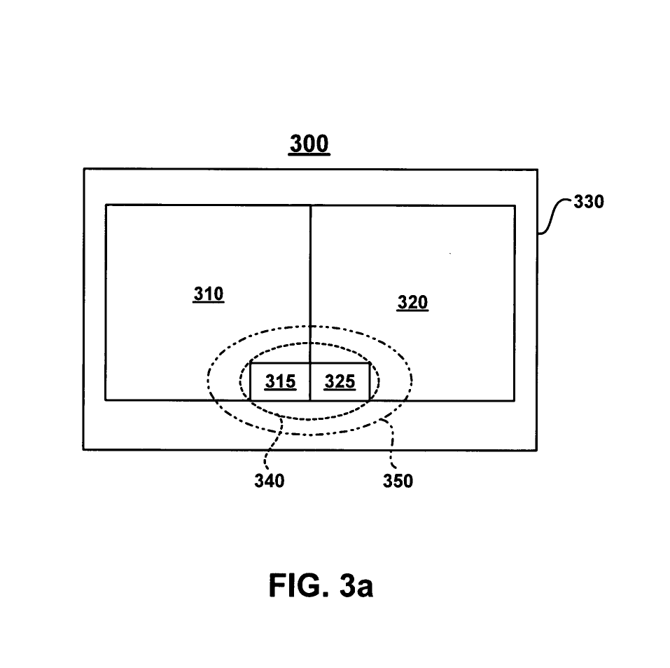

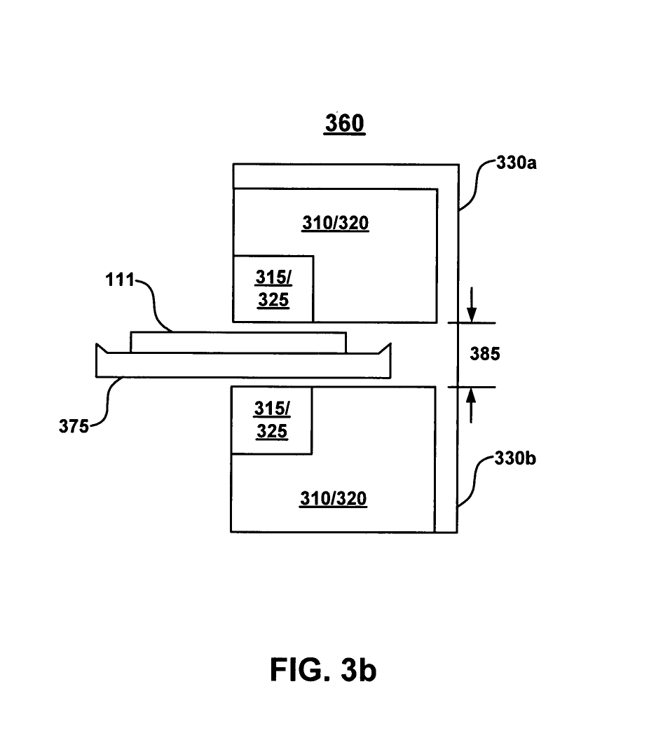

Referring now to FIG. 3a, a block diagram of one half of an exemplary bulk erase tool 300 is shown in accordance with one embodiment of the present invention. In other words, the bulk erase tool shown in FIG. 3a is merely a bottom or top half of the total bulk erase tool 300. A full version of the bulk erase tool is shown in FIG. 3b. However, only one half of the entire bulk erase tool 300 is provided during the discussion herein for purposes of brevity and clarity. In one embodiment, bulk erase tool 300 includes a first polarity main erase magnet 310, a second polarity main erase magnet 320, a first polarity cancel magnet 325 at a portion of the second polarity main magnet, a second polarity cancel magnet 315 at a portion of the first polarity main magnet 310 and an optional framework 330. Optionally, the bulk erase tool 300 also includes a tray for aligning the hard disk drive 111 to be erased.

In one embodiment, the first polarity cancel magnet 325 is embedded into a portion of the second polarity main magnet 320 and the second polarity cancel magnet 315 is embedded into a portion of the first polarity main magnet 310. Although, the first polarity cancel magnet 325 and the second polarity cancel magnet 315 are embedded in the main magnets in one embodiment, the cancel magnets may similarly be placed in openings formed in the main magnets, removably coupled with the main magnets, glued, or otherwise deployed to adjacent positions at an approximate front center portion of the main magnets of the bulk erase tool 300. However, the term embedded is used herein as one embodiment provided for purposes of brevity and clarity.

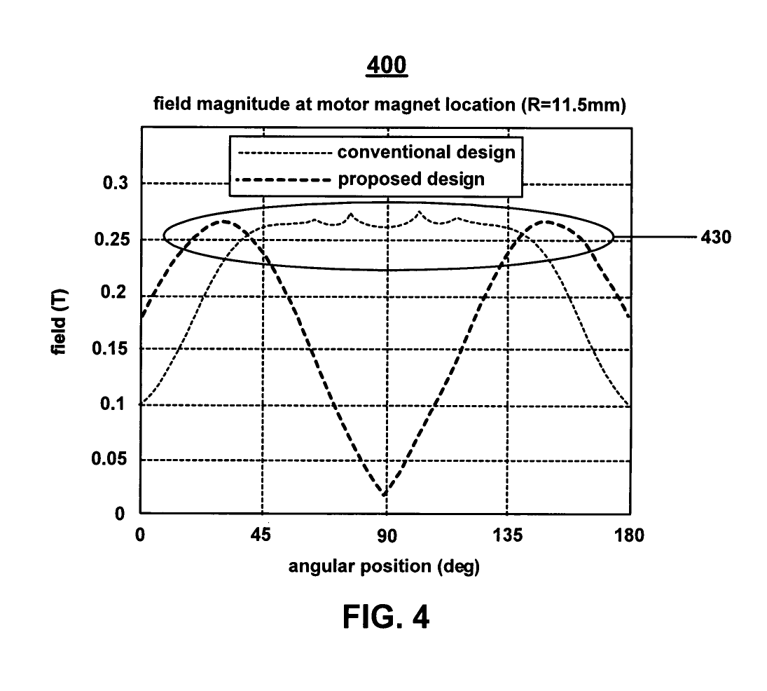

The first polarity cancel magnet 325 and the second polarity cancel magnet 315 provide reduced bulk erase tool field strength at a first portion 340 of the bulk erase tool 300. The graph of the magnetic field is clearly shown in FIG. 4. As described herein, and shown in FIG. 3a, in one embodiment, the first polarity cancel magnet 325 and the second polarity cancel magnet 315 reduce the bulk erase tool field strength approximately at a front center portion 340 of the bulk erase tool 300.

Beneficially, the bulk erase tool field strength is reduced at the first portion 340 of the bulk erase tool 300 thereby providing reduced demagnetization characteristics of the bulk erase tool with respect to a motor magnet, such as spindle motor 117, of a hard disk drive.

Moreover, the first and second polarity cancel magnets, 325 and 315 respectively, also provide an increase in the bulk erase tool field strength at a second portion 350 of the bulk erase tool 300. In general, the bulk erase tool field strength is increased at the second portion 350 of the bulk erase tool 300 to provide increased data erase characteristics of the bulk erase tool with respect to a data track of a disk of a hard disk drive.

Referring now to FIG. 3b, a side sectional view of a complete exemplary bulk erase tool 360 having both top and bottom magnet sets and the optional tray 375 is shown in accordance with one embodiment of the present invention. In one embodiment, bulk erase tool 360 includes a top portion 330a including a first polarity main erase top magnet 310 having a second polarity top cancel magnet 315 embedded at a portion thereof. Additionally, top portion 330a includes a second polarity main erase top magnet 320 having a first polarity top cancel magnet 325 embedded at a portion thereof. Bulk erase tool 360 also includes a bottom portion 330b including a first polarity main erase bottom magnet 310 having a second polarity bottom cancel magnet 315 embedded at a portion thereof. Additionally, bottom portion 330b includes a second polarity main erase bottom magnet 320 having a first polarity bottom cancel magnet 325 embedded at a portion thereof. As described herein, the first polarity top and bottom cancel magnets 325 and the second polarity top and bottom cancel magnets 315 are used for reducing the bulk erase tool field strength at the first portion of the bulk erase tool 340 of FIG. 3a. In other words, the bulk erase tool 360 of FIG. 3b provides the complete side-sectional view of a bulk erase tool consisting of two bulk erase halves shown in FIG. 3a.

Optionally, bulk erase tool 360 also includes the optional tray 375 for aligning the hard disk drive 111 to be erased. Although the tray 375 is shown in a location in the gap 385 of the bulk erase tool 360, it is understood that the tray 375 may be located in a plurality of arrangements with respect to the bulk erase tool 360. In general, the gap 385 refers to the distance (or gap length) between the upper magnets and the lower magnets.

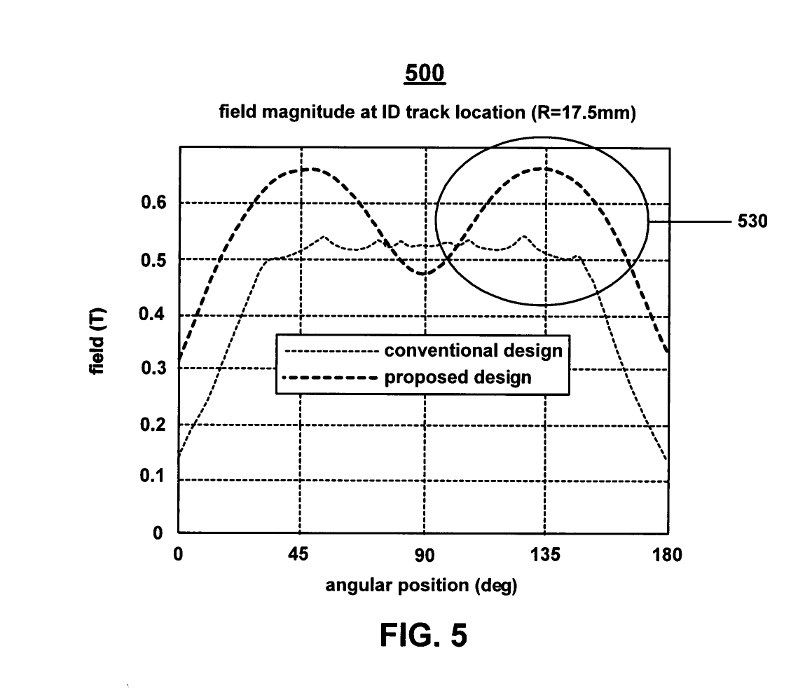

In one embodiment, the gap 385 distance is adjustable such that a hard disk drive 111 and the tray 375 can be inserted through the gap 385. For example, in FIGS. 4 and 5 the gap length is adjusted at 16 mm for a hard disk drive 111 of which thickness is 16 mm. However, it is understood that the gap length 385 is adjustable for a variety of widths and standoffs, such as the typical hard disk drive heights of 5 mm, 10 mm, 16 mm and 26 mm. Additionally, the gap 385 is adjustable and accommodating to almost any number to provide the correct standoff distance between the magnets 330a and 330b and the disk to be erased. Thus, the use of the 16 mm gap length is merely for purposes of brevity and clarity.

With reference now to FIG. 4, a graph 400 of the field magnitude of the bulk erase tool 300 is shown in accordance with one embodiment of the present invention. The graph 400 shows a magnetic field magnitude approximately 11.5 mm from the center of the spindle motor for a conventional bulk erase tool and the proposed bulk erase tool. This distance, e.g., 11.5 mm, is approximately the radial distance of the hard disk drive motor magnet 117. The, marked section 430 shows the reduced magnetic effects at the motor magnet 117 of the hard disk drive 111 with the same magnitude of the maximum field.

Referring now to FIG. 5, a graph 500 of the field magnitude of the bulk erase tool is shown in accordance with one embodiment of the present invention. In one embodiment, the graph 500 shows a magnetic field magnitude approximately 17.5 mm from the center of the spindle motor for a conventional erase tool and the proposed erase tool. This distance, e.g., 17.5 mm, is approximate the beginning of the hard disk drive ID track, e.g., the beginning of the pre-written timing information 225 of FIG. 2 and any customer data information 215 on the disk 115 of the hard disk drive 111. The, marked section 530 shows the increased magnetic effects at the ID track of the disk 115 of hard disk drive 111.

Thus, when comparing graph 400 to graph 500 it becomes apparent that by changing the location of the cancel magnets 315 and 325, e.g., being collocated with the main magnets 310 and 320, the canceling effect occurs at the front knee of the curve of the erase field which increases the slope of the field. Therefore, if the field at the motor magnet is the same (e.g., 2650G), the embodiments described herein can apply an additional 1000G or more of the field to the ID tracks of the disk 115. For example, when the size of the cancel magnet is optimized such that it provides strong canceling field but does not generate any undershoot of the field.

In one embodiment, the disclosed design shows at least 1000G improvement in the magnitude of the erase field with a magnet size such as, but not limited to, between approximately 50-150 millimeters. In one embodiment, the magnet grade is neomax-50. However, the disclosed magnet grade is provided as an example not as a limitation, and is stated herein merely for purposes of brevity and clarity.

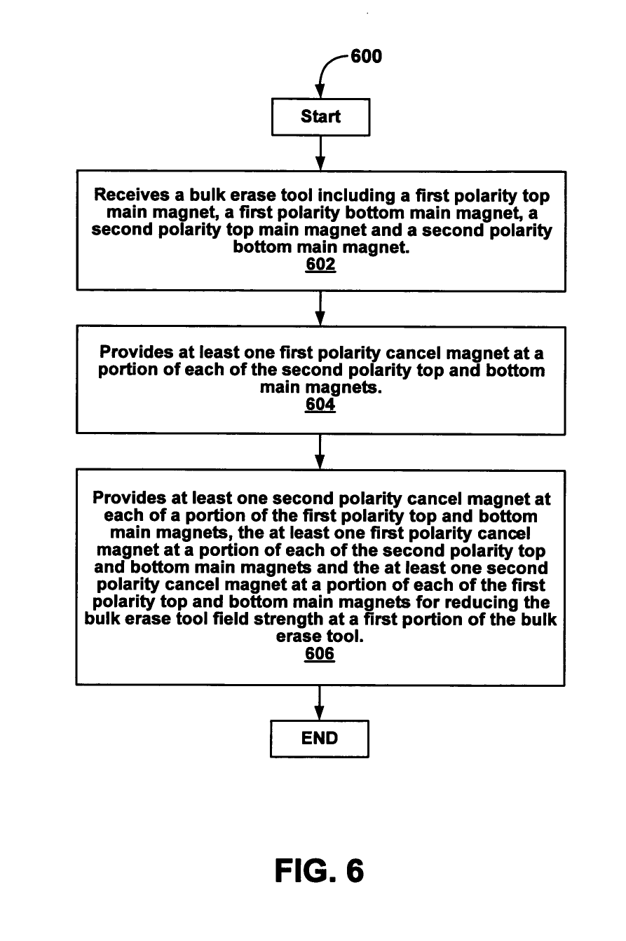

With reference now to FIG. 6, a flowchart 600 of a method for providing a bulk erase tool having a portion of reduced field strength is shown in accordance with one embodiment of the present invention. As described herein, a bulk erase tool 300 is a magnetic device for erasing the (servo or other) patterns on the disk 115 of a hard disk drive 111. The advantage of bulk erase over head erase is fast and easy operation. However, as disk coercivity becomes higher, the required magnetic field in the bulk erase tool 300 also becomes higher and increases the possibility of damaging the motor magnet 117 and heads 131. Embodiments described herein, provide a sharp transition of the magnetic field inside the bulk erase tool 300 (as shown in FIG. 5) which can be used for both longitudinal recording (LR) media and perpendicular recording (PR) media. Additionally, embodiments described herein provide a level of magnetic shielding for the motor magnet 117 to significantly reduce unintentional demagnetization of the motor magnet 117.

With reference to 602 of FIG. 6 and to FIG. 3b, one embodiment receives a bulk erase tool 360 having first polarity top and bottom main magnets 310 and second polarity top and bottom main magnets 320.

Referring now to 604 of FIG. 6 and to FIG. 3b, one embodiment provides at least one first polarity cancel magnet 325 at a portion of each of the second polarity top and bottom main magnets 320. As previously described herein, each cancel magnet 325 may be embedded in each of the second polarity top and bottom main magnets 320, placed in openings formed in the second polarity top and bottom main magnets 320, removably coupled with the second polarity top and bottom main magnets 320, glued to the second polarity top and bottom main magnets 320, or otherwise deployed on the second polarity top and bottom main magnets 320 of the bulk erase tool 360.

With reference now to 606 of FIG. 6 and to FIG. 3b, one embodiment provides at least one second polarity cancel magnet 315 at a portion of each of the first polarity top and bottom main magnets 310. As previously described herein, each cancel magnet 315 may be embedded in the first polarity top and bottom main magnets 310, placed in openings formed in the first polarity top and bottom main magnets 310, removably coupled with the first polarity top and bottom main magnets 310, glued to the first polarity top and bottom main magnets 310, or otherwise deployed on the first polarity top and bottom main magnets 310 of the bulk erase tool 300 or 360.

Advantageously, as shown in FIG. 3a, the at least one first polarity cancel magnet 325 and the at least one second polarity cancel magnet 315 provide a reduction in the bulk erase tool 300 field strength at a first portion 340 of the bulk erase tool 300. This reduction in the magnetic field strength is clearly shown in graph 400 of FIG. 4. The reduction of the bulk erase tool 300 field strength at the first portion 340 significantly reduces demagnetization characteristics of the bulk erase tool 300 with respect to the weaker motor magnet 117 within the hard disk drive 111 being subjected to the magnetic field of the bulk erase tool 300.

In one embodiment, the reduction of the bulk erase tool field strength is approximately at a front center portion of the bulk erase tool. However, the reduction in the field strength does not necessarily need to occur in the front center portion of the bulk erase tool 360. The cancel magnets 325 and 315 can be placed in almost any location along the abutment of the top and bottom main magnets 310 and 320 of the bulk erase tool 360. Thus, the use of the front center portion is merely for purposes of brevity and clarity.

Moreover, the at least one first and second polarity cancel magnets, 325 and 315, also provide an increase in the bulk erase tool field strength at a second portion 350 of the bulk erase tool. In so doing, the increase of the bulk erase tool field strength at the second portion 350 of the bulk erase tool 300 significantly increases the data erase characteristics of the bulk erase tool 300 with respect to the data track 225 of the disk 115 of the hard disk drive 111 without deleteriously affecting the magnet motor 117.

Thus, embodiments of the present invention provide a bulk erase tool. Moreover, embodiments provide a bulk erase tool having a portion of reduced field strength that significantly reduces motor magnet demagnetization. Additionally, embodiments provide a bulk erase tool having a portion of increased field strength that significantly increases the erase capabilities of the bulk erase tool in regard to both longitudinal and perpendicular recorded media. In so doing, the disk in a hard disk drive is more quickly, efficiently, and properly erased while deleterious magnetic effects on the motor magnet are reduced.

While the method of the embodiment illustrated in flowchart 600 show specific sequences and quantity of steps, the present invention is suitable to alternative embodiments. For example, not all the steps provided for in the methods are required for the present invention. Furthermore, additional steps can be added to the steps presented in the present embodiment. Likewise, the sequences of steps can be modified depending upon the application.

The alternative embodiment(s) of the present invention, a bulk erase tool is thus described. While the present invention has been described in particular embodiments, it should be appreciated that the present invention should not be construed as limited by such embodiments, but rather construed according to the below claims.

What is claimed is:

1. A bulk erase tool comprising:
a top bulk erase magnet assembly comprising:
a first polarity main erase top magnet, having a second polarity top cancel magnet at a portion thereof; and
a second polarity main erase top magnet, having a first polarity top cancel magnet at a portion thereof; and
a bottom bulk erase magnet assembly comprising:
a first polarity main erase bottom magnet, having a second polarity bottom cancel magnet at a portion thereof; and
a second polarity main erase bottom magnet having a first polarity bottom cancel magnet at a portion thereof, said first polarity top and bottom cancel magnets and said second polarity top and bottom cancel magnets for reducing the bulk erase tool field strength at said first portion of said bulk erase tool.

2. The bulk erase tool of claim 1 wherein said first polarity cancel top and bottom magnets are embedded into a portion of said second polarity main erase top and bottom magnets.

3. The bulk erase tool of claim 1 wherein said second polarity cancel top and bottom magnets are embedded into a portion of said first polarity main top and bottom magnets.

4. The bulk erase tool of claim 1 wherein said first polarity top and bottom cancel magnets and said second polarity top and bottom cancel magnets reduce said bulk erase tool field strength approximately at a front center portion of said bulk erase tool.

5. The bulk erase tool of claim 1 wherein the bulk erase tool field strength is reduced at said first portion of said bulk erase tool to provide reduced demagnetization characteristics of said bulk erase tool with respect to a motor magnet of a hard disk drive.

6. The bulk erase tool of claim 1 wherein said first and second polarity top and bottom cancel magnets provide an increase in the bulk erase tool field strength at a second portion of said bulk erase tool.

7. The bulk erase tool of claim 6 wherein the bulk erase tool field strength is increased at said second portion of said bulk erase tool to provide increased data erase characteristics of said bulk erase tool with respect to a data track of a disk of a hard disk drive.

8. A bulk erase tool having a portion of reduced field strength for erasing a hard disk drive, comprising:
a bulk erase tool comprising a first polarity top main magnet, a first polarity bottom main magnet, a second polarity top main magnet, and a second polarity bottom main magnet;
a first polarity top magnet at a potion of said second polarity top main magnet and a first polarity bottom cancel magnet at a portion of said second polarity bottom main magnet;
a second polarity top cancel magnet at a portion of said first polarity top main magnet and a second polarity bottom cancel magnet at a portion of said first polarity bottom main magnet, said first polarity top and bottom cancel magnets and said second polarity top and bottom cancel magnets for reducing the bulk erase tool field strength at a first portion of said bulk erase tool; and
a tray for orienting a hard disk drive with respect to said bulk erase tool such that a motor magnet of said hard disk drive is located at said first portion of said bulk erase tool having a reduced field strength.

9. The bulk erase tool of claim 8 wherein said first polarity top and bottom cancel magnet are embedded into a portion of said second polarity top and bottom main magnet and said second polarity top and bottom cancel magnet are embedded into a portion of said first polarity top and bottom main magnet.

10. The bulk erase tool of claim 8 wherein said first polarity top and bottom cancel magnets and said second polarity top and bottom cancel magnets reduce said bulk erase tool field strength approximately at a front center portion of said bulk erase tool.

11. The bulk erase tool of claim 8 wherein said tray is designed for orienting said motor magnet of said hard disk drive to reduce demagnetization characteristics of said bulk erase tool with respect to said motor magnet.

12. The bulk erase tool of claim 8 wherein said first and second polarity top and bottom cancel magnets provide an increase in the bulk erase tool field strength at a second portion of said bulk erase tool.

13. The bulk erase tool of claim 12 wherein said tray is designed for orienting said hard disk drive with respect to said bulk erase tool such that a data track portion of a disk of said hard disk drive is located at said second portion of said bulk erase tool to increase data erase characteristics of said bulk erase tool with respect to said data track portion of said disk.

14. The bulk erase tool of claim 12 wherein a transition is formed between said first portion of said bulk erase tool having a reduced field strength and said second portion of said bulk erase tool having an increased field strength, said transition increasing erase characteristics for a perpendicularly recorded data track.

15. A bulk erase tool for erasing a disk in a hard disk drive comprising:
a top bulk erase magnet assembly comprising:
a first polarity main erase top magnet, having a second polarity top cancel magnet embedded at a portion thereof; and
a second polarity main erase top magnet, having a first polarity top cancel magnet embedded at a portion thereof;
a bottom bulk erase magnet assembly comprising:
a first polarity main erase bottom magnet, having a second polarity bottom cancel magnet embedded at a portion thereof; and
a second polarity main erase bottom magnet having a first polarity bottom cancel magnet embedded at a portion thereof, said first polarity top and bottom cancel magnets and said second polarity top and bottom cancel magnets for reducing the bulk erase tool field strength at said first portion of said bulk erase tool; and
a tray for orienting a hard disk drive with respect to said bulk erase tool such that a motor magnet of said hard disk drive is located at said first portion of said bulk erase tool having a reduced field strength.

16. The bulk erase tool of claim 15 wherein said first polarity top and bottom cancel magnets and said second polarity top and bottom cancel magnets reduce said bulk erase tool field strength approximately at a front center portion of said bulk erase tool.

17. The bulk erase tool of claim 15 wherein said tray is designed for orienting said motor magnet of said hard disk drive to reduce demagnetization characteristics of said bulk erase tool with respect to said motor magnet.

18. The bulk erase tool of claim 15 wherein said first and second polarity top and bottom cancel magnets provide an increase in the bulk erase tool field strength at a second portion of said bulk erase tool.

19. The bulk erase tool of claim 18 wherein said tray is designed for orienting said hard disk drive with respect to said bulk erase tool such that a data track portion of a disk of said hard disk drive is located at said second portion of said bulk erase tool to increase data erase characteristics of said bulk erase tool with respect to said data track portion of said disk.

20. The bulk erase tool of claim 15 wherein said bulk erase tool is capable of erasing both a longitudinally formatted disk and a perpendicularly formatted disk.
